(19) United States
(12) Patent Application Publication
(10) Pub. No.: US 2013/0095627 A1
(43) Pub. Date: Apr. 18, 2013

(54) Methods of Forming Source/Drain Regions on Transistor Devices

(71) Applicants: Stefan Flachowsky, Dresden (DE); Matthias Kessler, Dresden (DE); Martin Gerhardt, Dresden (DE)

(72) Inventors: Stefan Flachowsky, Dresden (DE); Matthias Kessler, Dresden (DE); Martin Gerhardt, Dresden (DE)

(73) Assignee: GLOBALFOUNDRIES INC., Grand Cayman (KY)

(21) Appl. No.: 13/275,967

(22) Filed: Oct. 18, 2011

(51) Int. Cl. H01L 21/336

(52) U.S. Cl. 438/285; 438/300; 257/E21.409

(57) ABSTRACT

The present disclosure is directed to various methods of forming source/drain regions for transistor devices. In one example, a method disclosed herein includes the steps of forming a gate electrode structure for a transistor above a semiconducting substrate, performing a first etching process to define a plurality of initial cavities in the substrate proximate the gate structure for the transistor and after forming the initial cavities, performing an anneal process. The method continues with the steps of, after performing the anneal process, performing a second etching process on the initial cavities to define a plurality of final cavities and forming a semiconductor material in the final cavities.

### BACKGROUND OF THE INVENTION

1. Field of the Invention

Generally, the present disclosure relates to the manufacturing of sophisticated semiconductor devices, and, more specifically, to various methods of forming source/drain regions for transistor devices.

2. Description of the Related Art

The fabrication of advanced integrated circuits, such as CPU's, storage devices, ASIC's (application specific integrated circuits) and the like, requires the formation of a large number of circuit elements in a given chip area according to a specified circuit layout, wherein field effect transistors (NMOS and PMOS transistors) represent one important type of circuit elements that substantially determine performance of the integrated circuits. During the fabrication of complex integrated circuits using, for instance, MOS technology, millions of transistors, e.g., NMOS transistors and/or PMOS transistors are formed on a substrate including a crystalline semiconductor layer. A field effect transistor, irrespective of whether an NMOS transistor or a PMOS transistor is considered, typically comprises doped source and drain regions that are formed in a semiconducting substrate that are separated by a channel region. A gate insulation layer is positioned above the channel region and a conductive gate electrode is positioned above the gate insulation layer. By applying an appropriate voltage to the gate electrode, the channel region becomes conductive and current is allowed to flow from the source region to the drain region.

FIGS. 1A-1D depict one illustrative prior art process flow for partially forming a semiconductor device 100 that includes an illustrative PMOS transistor 100P and an illustrative NMOS transistor 100N. FIGS. 1A-1D will particularly focus on certain aspects of the formation of the PMOS transistor 100P. As shown in FIG. 1A, the process begins with the formation of illustrative gate electrode structures 14 for the PMOS transistor 100P and the NMOS transistor 100N in and above regions of the substrate 10 that are separated by an illustrative shallow trench isolation structure 12. The gate electrode structures 14 generally include a gate insulation layer 14A and one or more conductive gate electrode layers 14B. A gate cap layer 16, made of a material such as silicon nitride, is formed above the gate structures 14. Also depicted in FIG. 1A is an illustrative liner layer 18, made of a material such as silicon dioxide having a thickness of approximately 3-5 nm, that is conformally deposited on the device 100.

With continuing reference to FIG. 1A, illustrative silicon nitride spacers 20 have been formed adjacent the liner layer 18 for both the PMOS transistor 100P and the NMOS transistor 100N. Next, a masking layer (not shown), e.g., such a photoresist mask, is formed so as to cover the NMOS transistor 100N and expose the PMOS transistor 100P for further processing. Then, one or more ion implantation processes are performed on the exposed PMOS transistor 100P to form various doped regions in the substrate 10. More specifically, at the point depicted in FIG. 1A, an angled ion implant process may be performed using an N-type dopant material to form so-called halo implant regions 21P in the substrate 10 for the PMOS transistor 100P, and another vertical ion implant process may be performed using a P-type dopant material to form extension implant regions 23P for the PMOS transistor 100P. Thereafter, a very quick anneal process, such as a laser anneal process, may be performed at a temperature of about 1250° C. for about 10 milliseconds or so to repair the damaged lattice structure of the substrate 10 in the areas that were subjected to the ion implant processes discussed above. The implant regions 21P, 23P are depicted schematically and they are located in a position where they will be after the anneal process has been performed where some migration of the implanted dopant material may have occurred.

FIG. 1B also depicts the device 100 after several process operations have been performed on the device 100. More specifically, a hard mask layer 17, made of a material such as silicon nitride, is formed above the NMOS transistor 100N and the PMOS transistor 100P. The hard mask layer 17 may be formed by blanket-depositing the hard mask layer 17 across the device 100 and, thereafter, forming a masking layer (not shown), e.g., such a photoresist mask so as to cover the NMOS transistor 100N and expose the PMOS transistor 100P for further processing. Then an anisotropic etching process is performed to remove the hard mask layer 17 from above the PMOS transistor 100P. This process results in the formation of a second spacer 22 adjacent the spacer 20 on the PMOS transistor 100P. Next, an etching process is performed to define initial cavities 24 in areas of substrate 10 where source/drain regions for the PMOS transistor 100P will ultimately be formed. The depth and shape of the initial cavities 24 may vary depending upon the particular application. In one example, where the initial cavities 24 have an overall depth 25 of about 70 nm, the initial cavities 24 may be formed by performing an initial dry anisotropic etching process, such as a reactive ion etching (RIE) process using, for example, chlorine. In some cases, the initial cavities 24 may have a depth of about 40-50 nm. During the RIE process, damaged regions 30 are created in the substrate 10 proximate the corners of the initial cavities 24, as schematically depicted in FIG. 1B. The damaged regions 30 are believed to be created by the bombardment of ions during the RIE process. The damaged regions 30 may be in the form of general defects and in some cases all or part of the damaged regions 30 may be a region of amorphous silicon or at least an area with a non-crystalline structure.

With reference to FIG. 1C, the next process involves, performing a wet etching process using to produce so-called sigma-shaped cavities 24A in the substrate 10. The sigma-shaped cavities 24A have a unique shape due to the use of a crystalline orientation dependent etchant which has an etch rate that varies based upon the crystalline structure of the silicon substrate 10. Examples of such crystalline orientation dependent etchants include TMAH (tetra methyl ammonium hydroxide), KOH, EDP, etc. When etching crystalline silicon, TMAH exhibits a higher etch rate in the 110 direction than it does in the 100 direction. However, TMAH does not etch non-crystalline silicon, such as amorphous silicon or defect containing silicon, to any appreciable degree. Thus, the damaged regions 30 shown in FIG. 1B remain in the sigma-shaped cavities 24A, as shown in FIG. 1C. These damaged regions 30 may sometimes be referred to as silicon hillocks.

FIG. 1D depicts the device 100 after an epitaxial deposition process is performed to form epitaxial silicon germanium regions 26 in the sigma-shaped cavities 24A. In the depicted example, the regions 26 have an overfill portion that extends above the surface 10S of the substrate 10. The regions 26 may be formed by performing well know epitaxial deposition processes. In one example, in forming the silicon germanium regions 26, an initial undoped (no P-type dopant)silicon buffer layer (not shown) is grown in the sigma-shaped cavities 24A. The purpose of the buffer layer is to act as an intermediate lattice mismatch buffer layer (growing high-Ge-content SiGe (Ge>30%) directly on silicon will cause heavy dislocation defects. This can be avoided by increasing the lattice mismatch gradually, i.e., first a layer with, for example, about 20% Ge is formed on the silicon and then a second layer with, for example, about 40% Ge is formed top of the first layer (about 20% Ge). Using such an approach, dislocations are not likely to form since the transition from one layer to the other is not so strong in terms of lattice mismatch. Unfortunately, this buffer layer does not grow on the damaged hillock regions 30. After the buffer layer is formed, doped silicon germanium is grown on the buffer layer and directly on the damaged hillock regions 30 to fill the sigma-shaped cavities 24A. During this doped silicon germanium deposition process, schematically depicted dislocations 34 that originate in the area of the damaged hillock regions 30 are formed in the silicon germanium regions 26. In some cases, such dislocations 34 may extend throughout the silicon germanium regions 26. The dislocations 34 are undesirable for several reasons. The dislocations 34 tend to reduce charge carrier mobility due to enhanced scattering of the carriers when current is flowing. The dislocations 34 may also reduce the level of a compressive stress that was intentionally created in the substrate to improve the electrical performance of the PMOS transistor 100P. The device 100 in FIG. 1D has also be subjected to an etching process using, for example, hot phosphoric acid, to remove all of the exposed nitride materials, such as the hard mask layer 17, the spacers 20, the spacers 22 and the gate cap layer 16.

The present disclosure is directed to various methods and devices that may avoid, or at least reduce, the effects of one or more of the problems identified above.

### SUMMARY OF THE INVENTION

The following presents a simplified summary of the invention in order to provide a basic understanding of some aspects of the invention. This summary is not an exhaustive overview of the invention. It is not intended to identify key or critical elements of the invention or to delineate the scope of the invention. Its sole purpose is to present some concepts in a simplified form as a prelude to the more detailed description that is discussed later.

Generally, the present disclosure is directed to various methods of forming source/drain regions for transistor devices. In one example, a method disclosed herein includes the steps of forming a gate electrode structure for a transistor above a semiconducting substrate, performing a first etching process to define a plurality of initial cavities in the substrate proximate the gate structure for the transistor and after forming the initial cavities, performing an anneal process. The method continues with the steps of, after performing the anneal process, performing a second etching process on the initial cavities to define a plurality of final cavities and forming a semiconductor material in the final cavities.

Another illustrative method disclosed herein includes the steps of forming a gate electrode structure for a transistor above a semiconducting substrate, performing a first anisotropic etching process to define a plurality of initial cavities in the substrate proximate the gate structure for the transistor, and after forming the initial cavities, performing an anneal process at a temperature of at least 600° C. The method continues with the steps of, after performing the anneal process, performing a second etching process with a crystalline orientation dependent etchant on the initial cavities to define a plurality of final cavities and performing an epitaxial deposition process to form a semiconductor material in the final cavities.

### BRIEF DESCRIPTION OF THE DRAWINGS

The disclosure may be understood by reference to the following description taken in conjunction with the accompanying drawings, in which like reference numerals identify like elements, and in which:

FIGS. 1A-1D depict one illustrative prior art process flow for forming source/drain regions for an illustrative PMOS transistor; and

FIGS. 2A-2C depict various novel methods disclosed herein of forming source/drain regions for transistor devices.

While the subject matter disclosed herein is susceptible to various modifications and alternative forms, specific embodiments thereof have been shown by way of example in the drawings and are herein described in detail. It should be understood, however, that the description herein of specific embodiments is not intended to limit the invention to the particular forms disclosed, but on the contrary, the intention is to cover all modifications, equivalents, and alternatives falling within the spirit and scope of the invention as defined by the appended claims.

### DETAILED DESCRIPTION

Various illustrative embodiments of the invention are described below. In the interest of clarity, not all features of an actual implementation are described in this specification. It will of course be appreciated that in the development of any such actual embodiment, numerous implementation-specific decisions must be made to achieve the developers' specific goals, such as compliance with system-related and business-related constraints, which will vary from one implementation to another. Moreover, it will be appreciated that such a development effort might be complex and time-consuming, but would nevertheless be a routine undertaking for those of ordinary skill in the art having the benefit of this disclosure.

The present subject matter will now be described with reference to the attached figures. Various structures, systems and devices are schematically depicted in the drawings for purposes of explanation only and so as to not obscure the present disclosure with details that are well known to those skilled in the art. Nevertheless, the attached drawings are included to describe and explain illustrative examples of the present disclosure. The words and phrases used herein should be understood and interpreted to have a meaning consistent with the understanding of those words and phrases by those skilled in the relevant art. No special definition of a term or phrase, i.e., a definition that is different from the ordinary and customary meaning as understood by those skilled in the art, is intended to be implied by consistent usage of the term or phrase herein. To the extent that a term or phrase is intended to have a special meaning, i.e., a meaning other than that understood by skilled artisans, such a special definition will be expressly set forth in the specification in a definitional manner that directly and unequivocally provides the special definition for the term or phrase.

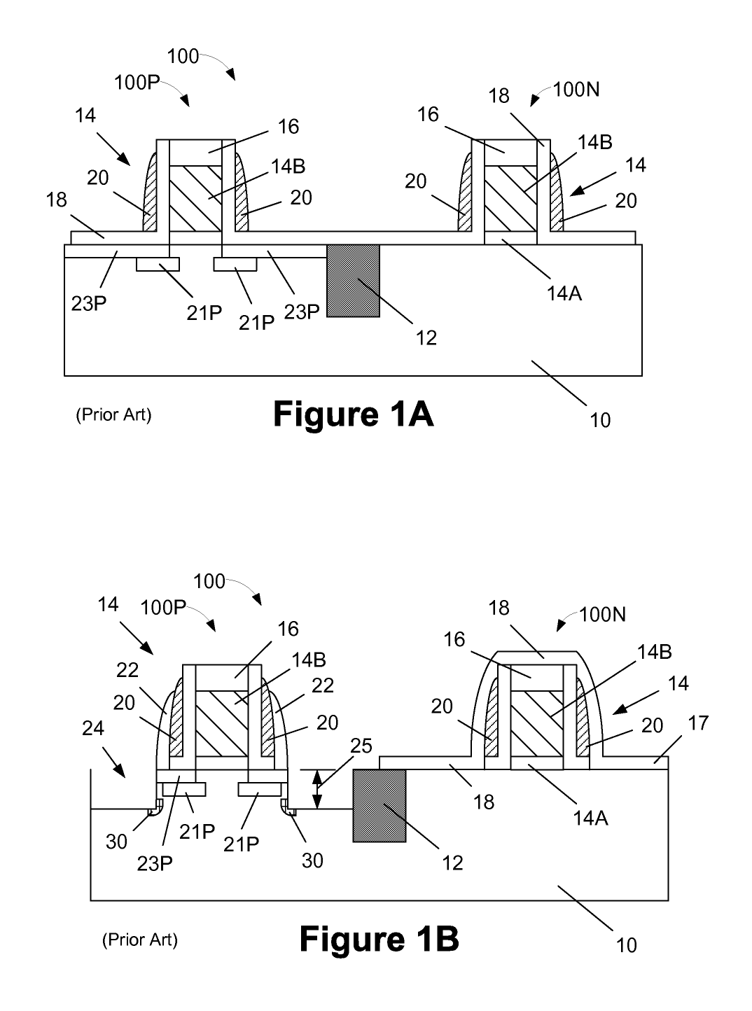

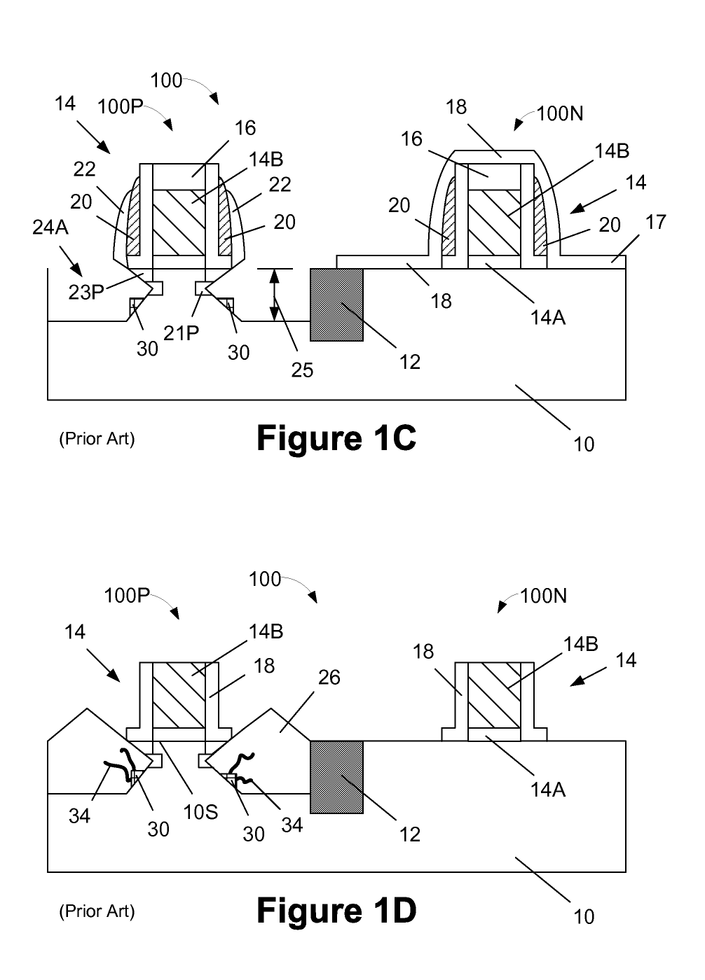

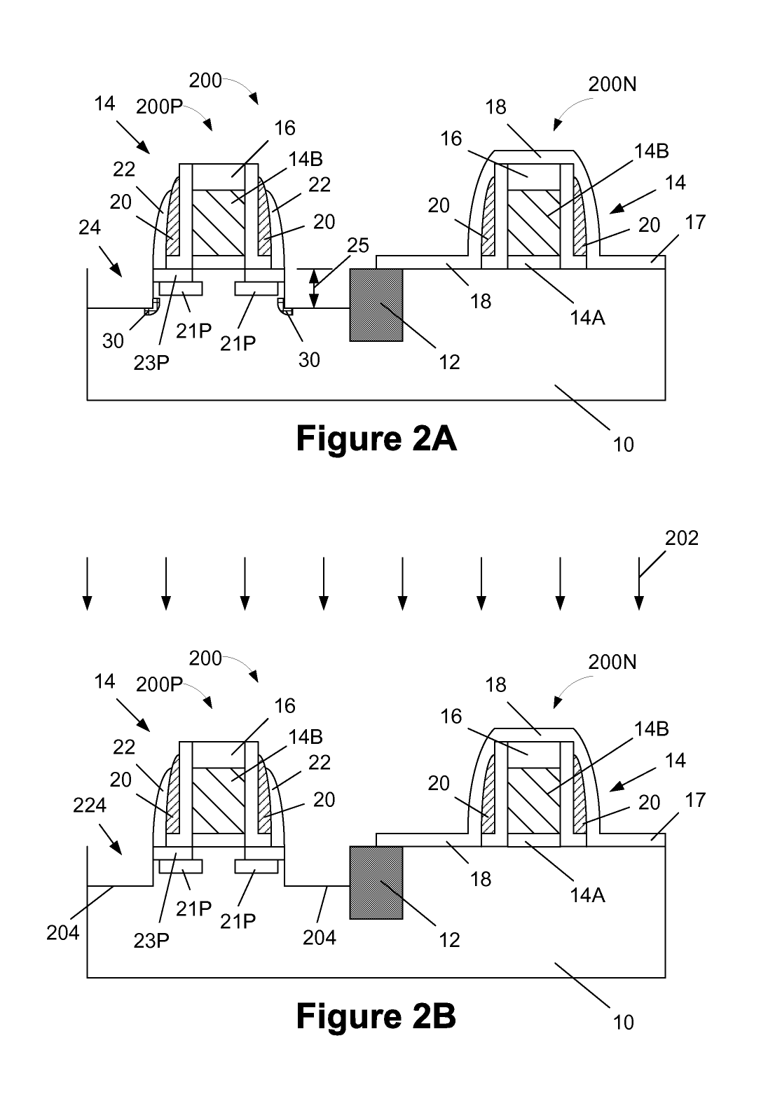

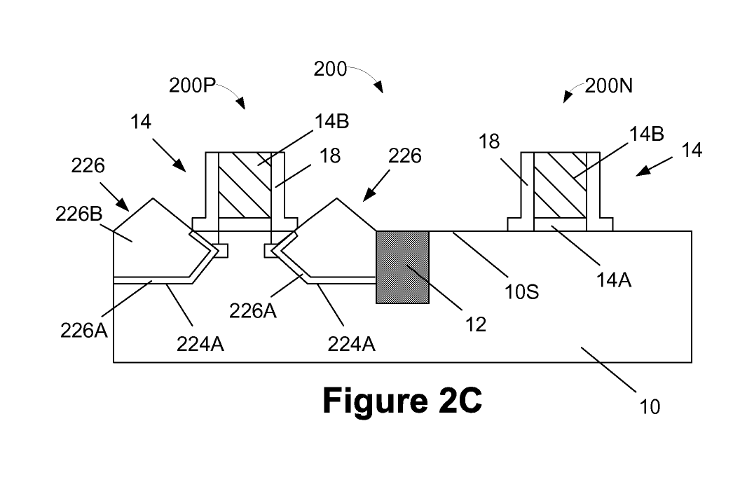

The present disclosure is directed to various methods of forming source/drain regions for transistor devices. Such a novel process flow may tend to reduce the undesirable recessing of the substrate, as discussed in the background section of this application. Moreover, such a novel process flow may tend to at least reduce some of the problems associated with the illustrative prior art process flow described previously. As will be readily apparent to those skilled in the art upon a complete reading of the present application, the present method is applicable to a variety of technologies, e.g., MOS-based technologies, etc., and is readily applicable to a variety of devices, including, but not limited to, ASICs, logic devices, memory devices, etc. With reference to FIGS. 2A-2C, various illustrative embodiments of the methods disclosed herein will now be described in more detail. To the extent that like numbers of various components is used in FIGS. 2A-2C and FIGS. 1A-1D, the previous discussion of those components in connection with the device 100 applies equally as well to the device 200.

FIG. 2A is a simplified view of an illustrative semiconductor device 200 at an early stage of manufacture that corresponds to the stage of manufacture shown in FIG. 1B for the semiconductor device 100. Thus, the description of the process of the device 100 up to the point depicted in FIG. 1B applies equally to the device 200. The semiconductor device 200 includes an illustrative PMOS transistor 200P and an illustrative NMOS transistor 200N. As shown in FIG. 2A, the device 200 includes illustrative gate structures 14 for the PMOS transistor 200P and the NMOS transistor 200N, an illustrative cap layer 16 and an illustrative liner layer 18. The substrate 10 may have a variety of configurations, such as the depicted bulk silicon configuration. The substrate 10 may also have a silicon-on-insulator (SOI) configuration that includes a bulk silicon layer, a buried insulation layer and an active layer, wherein semiconductor devices are formed in and above the active layer. Thus, the terms substrate or semiconductor substrate should be understood to cover all forms of semiconductor structures. The substrate 10 may also be made of materials other than silicon. As will be recognized by those skilled in the art after a complete reading of the present application, the gate structures 14 may be of any desired construction and comprised of any of a variety of different materials, such as one or more conductive layers made of polysilicon or a metal, etc., and one or more layers of insulating material, such as silicon dioxide, a high-k material, etc. Additionally, the gate structure 14 for the NMOS transistor 200N may have different material combinations as compared to a gate structure 14 for the PMOS transistor 200P. Thus, the particular details of construction of gate structure 14, and the manner in which the gate structures 14 are formed, should not be considered a limitation of the present invention. For example, the gate structures 14 may be made using so-called “gate-first” or “gate-last” techniques.

With continuing reference to FIG. 2A, a masking layer (not shown), e.g., such a photoresist mask, is formed so as to cover the NMOS transistor 200N and expose the PMOS transistor 200P for further processing. Then, one or more ion implantation processes are performed on the exposed PMOS transistor 200P to form various doped regions in the substrate 10. More specifically, at the point depicted in FIG. 2A, an angled ion implant process may be performed using an N-type dopant material to form so-called halo implant regions 21P in the substrate 10 for the PMOS transistor 200P, and another vertical ion implant process may be performed using a P-type dopant material to form extension implant regions 23P for the PMOS transistor 200P. Thereafter, a very quick anneal process, such as a laser anneal process, may be performed at a temperature of about 1250° C. for about 10 milliseconds or so to repair the damaged lattice structure of the substrate 10 in the areas that were subjected to the ion implant processes discussed above.

Next, an etching process is performed to define initial cavities 24 in areas of substrate 10 where source/drain regions for the PMOS transistor 200P will ultimately be formed. The depth and shape of the initial cavities 24 may vary depending upon the particular application. In one example, the initial cavities 24 may be formed by performing an initial dry anisotropic etching process, such as a reactive ion etching (RIE) process using, for example, chlorine. In some cases, the initial cavities 24 may have a depth of about 40-50 nm. As noted earlier, during the RIE process, damaged regions 30 are created in the substrate 10 proximate the corners of the initial cavities 24, as schematically depicted in FIG. 2A. The damaged regions 30 may be in the form of general defects and in some cases all or part of the damaged regions 30 may be a region of amorphous silicon or at least an area with a non-crystalline structure.

Next, as shown in FIG. 2B, a recrystallization anneal process 202 is performed on the device 200 after the initial cavities 24 are formed to recrystallize the damaged regions 30. Thus, the damaged regions 30 are not depicted in FIG. 2B as the recrystallization anneal process 202 results in crystalline initial cavities 224. The recrystallization anneal process 202 may be performed at a relatively low temperature for a few minutes or it may be performed at a higher temperature for a shorter period of time. In one illustrative example, the recrystallization anneal process 202 may be performed at a temperature of at least about 600° C. for a duration of about 10 minutes in a furnace. In another illustrative example, the recrystallization anneal process 202 may performed at a temperature of about 1000° C. for about 5 seconds or it may be performed at a temperature of about 1200° C. for a duration of about 2 ms using a laser anneal or flash anneal technique. After the recrystallization anneal process 202 is performed, the surface 204 of the crystalline initial cavities 224 is a crystalline surface where the crystalline orientation dependent etchant that will be used to form the sigma-shaped cavities 224A (discussed below) can work as intended.

FIG. 2C depicts the device 200 after several process operations have been performed. First, a wet etching process is performed to produce final cavities 224A in the substrate 10. In one embodiment, the final cavities 224A may be or sigma-shaped. The etching process is performed using a crystalline orientation dependent etchant which has an etch rate that varies based upon the crystalline structure of the silicon substrate 10. Examples of such crystalline orientation dependent etchants include TMAH (tetra methyl ammonium hydroxide), KOH, EDP, etc. As noted previously, when etching crystalline silicon, TMAH exhibits a higher etch rate in the 110 direction than it does in the 100 direction.

FIG. 2C also depicts the device 200 after one or more processes are performed to form semiconductor material regions 226 in the final cavities 224A. The semiconductor material regions 226 may be comprised of a variety of materials, e.g., silicon germanium, silicon carbon, etc., and they may be formed by performing a variety of known processing techniques. In one illustrative embodiment, the semiconductor material regions 226 are silicon germanium and they are formed by performing an epitaxial deposition process. In the depicted example, the semiconductor material regions 226 have an overfill portion that extends above the surface 10S of the substrate 10. In one example, where the semiconductor material regions 226 are comprised of silicon germanium, an initial undoped (no P-type dopant) silicon buffer layer 226A is grown in the sigma-shaped cavities 224A. In some cases, this silicon buffer layer 226A may have a thickness of about 10-20 nm. After the silicon buffer layer 226A is formed, silicon germanium 226B is grown on the silicon buffer layer 226A to fill the final cavities 224A. The amount of germanium used in forming the silicon germanium material may vary depending upon the particular application.

At this point, the device 200 may be completed by performing various well-known operations. Using the novel processing disclosed herein, the semiconductor material regions 226 may be formed in substantially defect-free, crystalline final cavities 224A. Such processing will enable the formation of semiconductor material regions 226 that are free of the dislocations 34 described in the background section of this application.

The particular embodiments disclosed above are illustrative only, as the invention may be modified and practiced in different but equivalent manners apparent to those skilled in the art having the benefit of the teachings herein. For example, the process steps set forth above may be performed in a different order. Furthermore, no limitations are intended to the details of construction or design herein shown, other than as described in the claims below. It is therefore evident that the particular embodiments disclosed above may be altered or modified and all such variations are considered within the scope and spirit of the invention. Accordingly, the protection sought herein is as set forth in the claims below.

What is claimed:

1. A method, comprising:
forming a gate electrode structure for a transistor above a semiconducting substrate;
performing a first etching process to define a plurality of initial cavities in said substrate proximate said gate structure for said transistor;
after forming said initial cavities, performing an anneal process;
after performing said anneal process, performing a second etching process on said initial cavities to define a plurality of final cavities; and
forming a semiconductor material in said final cavities.

2. The method of claim 1, wherein said transistor is a PMOS transistor.

3. The method of claim 1, wherein performing said first etching process comprises performing an anisotropic etching process to define said plurality of initial cavities.

4. The method of claim 1, wherein performing said anneal process comprises performing said anneal process at a temperature of at least 600° C.

5. The method of claim 1, wherein performing said second etching process comprised performing said second etching process with a crystalline orientation dependent etchant on said initial cavities to define said plurality of final cavities.

6. The method of claim 5, wherein crystalline orientation dependent etchant is one of TMAH, KOH or EDP.

7. The method of claim 1, wherein said step of forming said semiconductor material in said final cavities comprises performing an epitaxial deposition process.

8. The method of claim 1, wherein said semiconductor material comprises one of silicon germanium material or silicon carbon.

9. A method, comprising:
forming a gate electrode structure for a transistor above a semiconducting substrate;
performing a first anisotropic etching process to define a plurality of initial cavities in said substrate proximate said gate structure for said transistor;
after forming said initial cavities, performing an anneal process at a temperature of at least 600° C.;
after performing said anneal process, performing a second etching process with a crystalline orientation dependent etchant on said initial cavities to define a plurality of final cavities; and
performing an epitaxial deposition process to form a semiconductor material in said final cavities.

10. The method of claim 9, wherein said transistor is a PMOS transistor.

11. The method of claim 9, wherein crystalline orientation dependent etchant is one of TMAH, KOH or DEP.

12. The method of claim 9, wherein said semiconductor material comprises one of silicon germanium material or silicon carbon.

13. A method, comprising:
forming a gate electrode structure for a PMOS transistor above a semiconducting substrate;
performing a first anisotropic etching process to define a plurality of initial cavities in said substrate proximate said gate structure for said PMOS transistor;
after forming said initial cavities, performing an anneal process at a temperature of at least 600° C.;
after performing said anneal process, performing a second etching process using one of TMAH, KOH or EDP as the etchant on said initial cavities to define a plurality of final cavities; and
performing an epitaxial deposition process to form a silicon germanium semiconductor material in said final cavities.
